(19) United States
(12) Patent Application Publication
(10) Pub. No.: US 2007/0046341 A1
(43) Pub. Date: Mar. 1, 2007

(54) Method and apparatus for generating a power on reset with a low temperature coefficient

(76) Inventor: Toru Tanzawa, Tokyo (JP)

Correspondence Address: TRASK BRITT, P.C./ MICRON TECHNOLOGY, P.O. BOX 2550, SALT LAKE CITY, UT, 84110, US

(21) Appl. No.: 11/215,802

(22) Filed: Aug. 29, 2005

(30) Foreign Application Priority Data
Aug. 26, 2005 (JP) 2005-246270

(51) Int. Cl. H03L 7/00

(52) U.S. Cl. 327/143

(57) ABSTRACT

Methods and apparatuses for generating a power-on-reset signal that is substantially independent of temperature change are disclosed. A reset circuit comprises a voltage generator, a first resistance element, a current generator, and a comparator. The voltage generator is configured for generating a first voltage signal having a negative temperature coefficient. The first resistance element is operably coupled between a supply voltage and a second voltage signal. The current generator is operably coupled to the second voltage signal and configured for sinking a reference current having a positive temperature coefficient and an offset current. The comparator is configured for comparing the first voltage signal to the second voltage signal to generate a reset signal. The present invention further includes semiconductor devices, semiconductor wafers, and electronic systems including the method or apparatus for generating the power-on-reset signal.

### BACKGROUND OF THE INVENTION

### Field of the Invention

The present invention relates to power on reset circuits. More specifically, the present invention relates to circuits and methods for generating a power-on-reset signal with a low temperature coefficient, that is robust across process variations, and occurs at a supply voltage above a bandgap voltage.

Electronic systems, and the integrated circuits in those systems, need robust and stable signals indicating that power has been applied and that the power is stable above an acceptable threshold.

During power up and power down, reset procedures are complicated by the fact that power supplies can be noisy. The power supplies may create significant glitches above and below the nominal voltage present as the supply voltage ramps up. For example, as the supply voltage (often referred to as VCC or VDD) ramps up, it rises to a desired supply voltage level. At a voltage point between zero volts and the desired supply voltage, an acceptable threshold is reached wherein the circuits attached to that supply voltage may operate properly. However, during the ramp up, but after reaching this acceptable threshold, the supply voltage may glitch below the acceptable threshold, triggering a power down sequence, causing incorrect function in logic circuits, or causing incorrect function in analog circuits.

Many techniques exist for generating a power-on-reset signal. A voltage reference may be created from a traditional and simple voltage divider circuit using resistors in series. Unfortunately, the resultant reference voltage is a direct function of the supply voltage and may reproduce the potential glitches, generating undesirable results for a power-on-reset procedure. In addition, resistor voltage dividers may be temperature dependant, generating a power-on-reset signal at different voltage levels depending on the temperature. Voltage dividers are, therefore, not an adequate solution when substantial temperature independence is required.

Bandgap references are quite flexible and may generate reference voltages that are substantially voltage supply independent and substantially temperature independent. Conventional bandgap reference circuits generate a power-on-reset signal at the point where the supply voltage exceeds the bandgap of silicon (i.e., about 1.25 volts).

A circuit diagram of a conventional bandgap reference power-on-reset (POR) circuit 10 is shown in FIG. 1. The bandgap reference includes, a comparator 15, two diode connected bipolar transistors (28 and 38), and resistors (22, 32, and 36). The bipolar transistors (28 and 38) are configured with junction areas of relative size such that bipolar transistor 28 has a P-N junction area with a relative size of one, and bipolar transistor 38 has a P-N junction area that is N times the size of bipolar transistor 28.

Generally, a bandgap reference is derived from the principal that two diodes of different sizes, but with the same emitter current, will have different current densities and, as a result, slightly different voltage drops across the P-N junction. Furthermore, P-N junctions have a negative temperature coefficient wherein changes in the voltage drop across the P-N junction are inversely proportional to changes in temperature. In other words, as temperature rises, the voltage drop across a P-N junction falls. For example, for silicon, the voltage drop across a P-N junction is inversely proportional to temperature changes at about −2.2 mV/° C.

Thus, for a circuit wherein resistors 22 and 32 have the same value, the voltage drop across the first bipolar transistor 28 is equal to the combination of the voltage drop across the second bipolar transistor 38 and the voltage drop across resistor 36. As a result, the voltage drop across resistor 36 represents the difference between the voltage drop across the first transistor 28 and the voltage drop across the second transistor 38. This difference generally may be referred to as ΔV_{be} indicating that it represents the difference in voltage drop between the two bipolar transistors 28 and 38. ΔV_{be} may also be referred to as a voltage that is Proportional to Absolute Temperature (PTAT) because the voltage adjusts in proportion to temperature change with a positive temperature coefficient substantially opposite to the negative temperature coefficient of the first bipolar transistor 28 such that the output signal 18 remains substantially temperature independent.

Resistance values of the resistors (22, 32, and 36) and the relative sizes of the p-n junction of the bipolar transistors (28 and 38) may be selected such that the power-on-reset signal 18 is asserted when the supply voltage exceeds the bandgap voltage in a manner that is substantially independent from temperature. However, in some systems, the supply voltage may still be quite noisy at about 1.25 volts or circuitry in the system may require a higher supply voltage before reliable operation is possible.

To generate a POR signal at a higher supply voltage, other circuits have been proposed. The power-on-reset circuit of FIG. 2 is similar to the circuit of FIG. 1, including a comparator 15′, two diode connected bipolar transistors (28′ and 38′), and resistors (22′, 32′, and 36′). However, the embodiment of FIG. 2 includes an additional resistor 52 between the bandgap reference and VCC 50′. This configuration creates a voltage divider between VCC 50′ and the bandgap voltage reference, which raises the overall VCC level at which the power-on-reset signal is asserted. However, the circuit of FIG. 2 is temperature dependent due to the positive temperature coefficient of the current flowing through the additional resistor 52.

There is a need for a power-on-reset signa temperature independent and may generate the power-on-reset signal at a supply voltage above the bandgap voltage.

### BRIEF SUMMARY OF THE INVENTION

The present invention in a number of embodiments includes methods and apparatuses for generating a reset signal that is substantially temperature independent and at a supply voltage above a bandgap voltage.

In one embodiment of the invention, a reset circuit comprises a voltage generator, a first resistance element, a current generator, and a comparator. The first resistance element is operably coupled between a supply voltage and a first voltage signal. The current generator is operably coupled to the first voltage signal and configured for sinking a reference current having a positive temperature coefficient and an offset current. The voltage generator is configured for generating a second voltage signal having a negative temperature coefficient. The comparator is configured for comparing the first voltage signal to the second voltage signal to generate a reset signal.

Another embodiment of the present invention comprises a reset circuit including a comparator having a first input, a second input, and a comparison result configured as a reset signal. The reset circuit further includes a first resistance element operably coupled between a supply voltage and the first input. Similarly, a second resistance element is operably coupled between the supply voltage and the second input. From the first input, a fourth resistance element is operably coupled in parallel with a series combination of a third resistance element and a first P-N junction element configured in a forward bias direction between the third resistance element and a ground. A second P-N junction element is operably coupled in a forward bias direction between the second input and the ground.

Another embodiment of the present invention comprises a semiconductor device including at least one reset circuit according to an embodiment of the invention described herein.

Another embodiment of the present invention comprises at least one semiconductor device fabricated on a semiconductor wafer, wherein the at least one semiconductor device includes at least one reset circuit according to an embodiment of the invention described herein.

Yet another embodiment in accordance with the present invention comprises an electronic system including at least one input device, at least one output device, at least one processor, and at least one memory device. The at least one memory device includes at least one reset circuit according to an embodiment of the invention described herein.

Another embodiment of the invention comprises a method of generating a reset signal. The method comprises generating a reference current having a positive temperature coefficient and an offset current. The method further comprises generating a first voltage signal as a voltage drop from a supply voltage, by guiding the reference current through a first resistance element operably coupled between the supply voltage and the reference current. The method further comprises generating a second voltage signal having a negative temperature coefficient and comparing the first voltage signal to the second voltage signal to generate the reset signal.

### BRIEF DESCRIPTION OF THE SEVERAL VIEWS OF THE DRAWINGS

FIG. 1 is a circuit diagram of a conventional power-on-reset circuit;

FIG. 2 is a circuit diagram of another conventional power-on-reset circuit;

FIG. 3 is a circuit diagram of an embodiment of the present invention for generating a reset signal at a supply voltage above the bandgap voltage;

FIG. 4 is a circuit diagram of another embodiment of the present invention for generating a reset signal at a supply voltage above the bandgap voltage;

FIG. 5A is a circuit diagram of another embodiment of the present invention for generating a reset signal at a supply voltage above the bandgap voltage;

FIG. 5B is a circuit diagram of another embodiment of the present invention for generating a reset signal at a supply voltage above the bandgap voltage;

FIG. 6 is a graphical illustration of various currents according to the FIG. 5A embodiment;

FIG. 7 is a graphical illustration of simulation results for various voltage signals according to the FIG. 5A embodiment;

FIG. 8 is a semiconductor wafer containing a plurality of semiconductor devices containing a reset circuit according to the present invention; and

FIG. 9 is a computing system diagram showing a plurality of semiconductor memories containing a reset circuit according to the present invention.

### DETAILED DESCRIPTION OF THE INVENTION

The present invention in a number of embodiments includes methods and apparatuses for generating a power-on-reset signal that is substantially temperature independent, substantially supply voltage independent, and at a voltage output above a bandgap voltage.

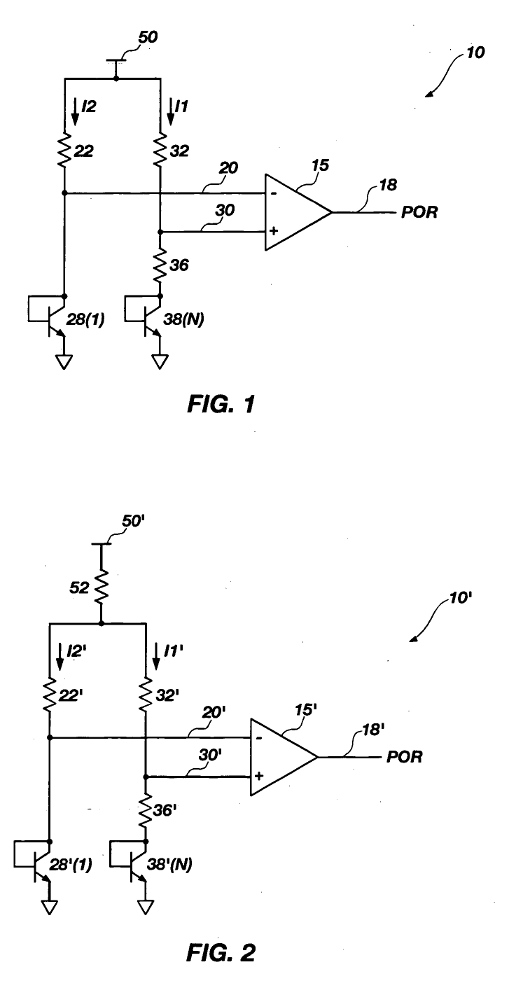

Some circuits in this description may contain a well-known circuit configuration known as a diode-connected transistor. A diode-connected transistor is formed when the gate and drain of a Complementary Metal Oxide Semiconductor (CMOS) transistor are connected together, or when the base and collector of a bipolar transistor are connected together. For example, in the circuit shown in FIG. 1, the bipolar transistors 28 and 38 are connected in a diode configuration. When connected in this fashion the transistor operates with voltage to current properties similar to a p-n junction diode.

Historically, voltage references corresponding to the bandgap voltage of silicon have been defined using the voltage from the base to emitter (V_{be}) of a bipolar junction transistor. However, any device creating a P-N junction may be used rather than a bipolar transistor, such as, for example a conventional diode or a CMOS device connected in a diode configuration. While the bandgap voltage may be obtained from a variety of devices in the various embodiments of the invention, suitable devices used to generate the bandgap voltage may be generally referred to as diodes, P-N junction elements, diode-connected CMOS transistors, and diode connected bipolar transistor. In addition, the voltage drop generated by any of these devices may be referred to using the historical V_{be} nomenclature.

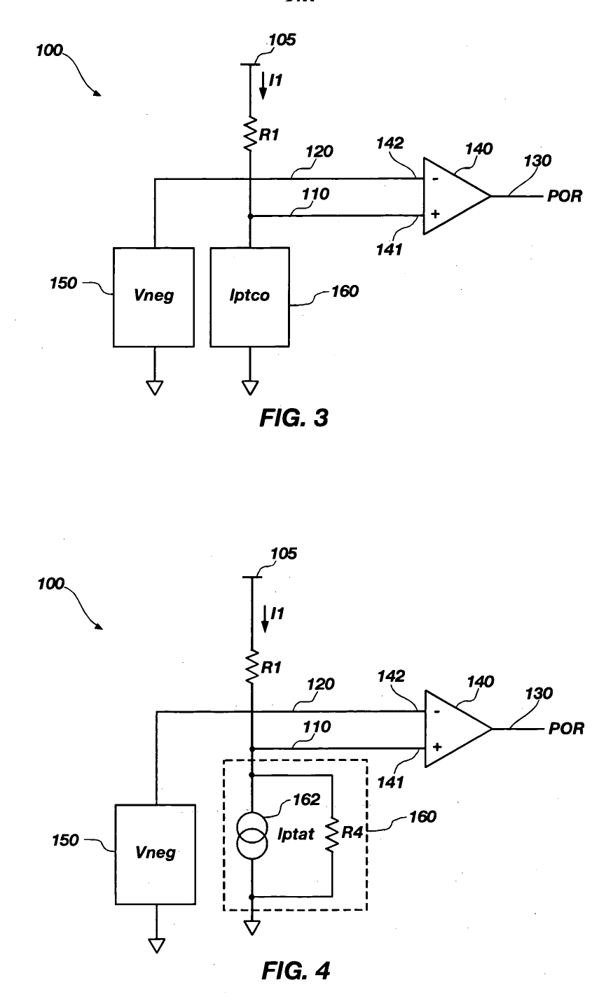

FIG. 3 illustrates a circuit diagram of a reset circuit 100, to show the theory of generating a reset signal 130 that is substantially independent from temperature change and that is asserted when the supply voltage 105 is above the bandgap voltage by a predefined amount. A current generator 160 (may also be referred to as Positive Temperature Coefficient with an Offset current I_{ptco}), generates a current with a positive temperature coefficient, wherein the current increases as temperature increases. The current also includes an offset current, or base level current as is explained more fully below. A first resistance element R1 provides a voltage drop between the supply voltage 105 and the current generator 160, resulting in a first voltage signal 110 with a positive temperature coefficient and an offset voltage. A voltage generator 150 (may also be referred to as Vneg) generates a second voltage with a negative temperature coefficient wherein the voltage decreases as temperature increases. The first voltage signal 110 is operably coupled to a first input 141 of a comparator 140 and the second voltage signal 120 is operably coupled to a second input 142 of the comparator 140. The reset signal 130 is generated by the output of the comparator 140.

FIG. 4 illustrates a circuit diagram of a reset circuit 100, to show the theory of generating a reset signal 130 that is substantially independent from temperature change and that is asserted when the supply voltage 105 is above the bandgap voltage by a predefined amount. In the FIG. 4 embodiment, the current generator 160, which generates I_{ptco}, comprises resistance element R4 and a current generator 162 configured to generate a current that is proportional to absolute temperature Iₚₜₐₜ. A first resistance element R1 provides a voltage drop between the supply voltage 105 and the current generator 160, resulting in a first voltage signal 110 with a positive temperature coefficient and an offset voltage. As with the FIG. 3 embodiment, voltage generator 150 generates a second voltage with a negative temperature coefficient wherein the voltage decreases as temperature increases. The first voltage signal 110 is operably coupled to a first input 141 of a comparator 140 and the second voltage signal 120 is operably coupled to a second input 142 of the comparator 140. The reset signal 130 is generated by the output of the comparator 140.

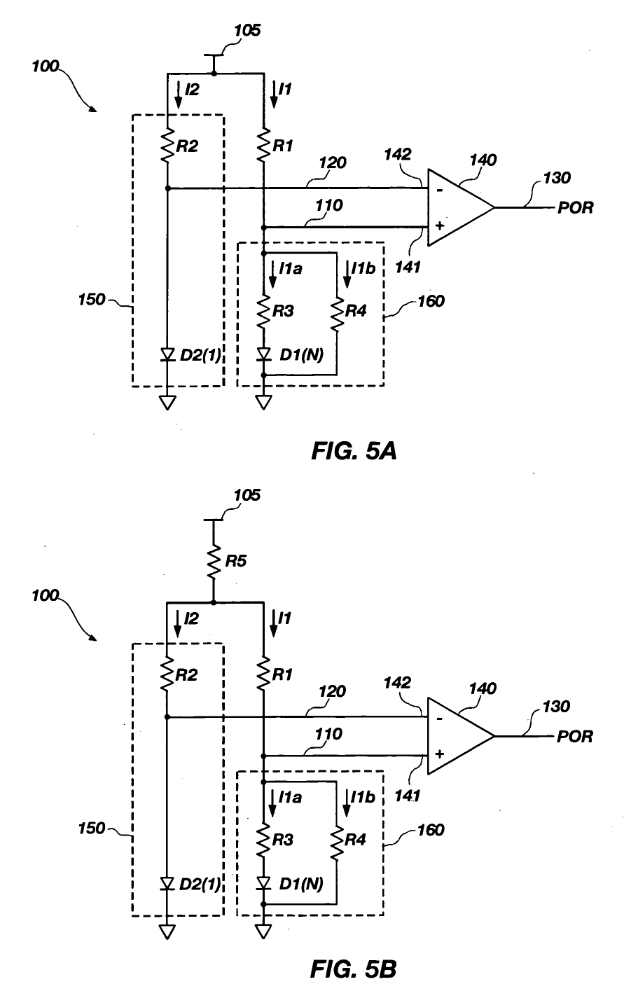

FIG. 5A illustrates an embodiment of the present invention with exemplary embodiments of the voltage generator 150 and the current generator 160. The reset circuit 100 includes the comparator 140, the voltage generator 150, the current generator 160, and the first resistance element R1. The current generator 160 includes a first P-N junction element D1, a third resistance element R3, and a fourth resistance element R4. The voltage generator 150 includes a second P-N junction element D2 and a second resistance element R2.

The resistance elements (R1, R2, R3, and R4) may be formed using various circuit elements and connections to generate a relatively constant resistance value. Some contemplated resistor implementations include, for example, discrete resistors, a length of N+ doped region as a resistor element, a length of P+ doped region as a resistor element, a length of polysilicon as a resistor element, an n-channel transistor connected such that it operates in the saturation region, and a p-channel transistor connected such that it operates in the saturation region. The comparator may be any comparator suitable for comparing analog voltages in the range desired, such as, for example, a differential amplifier.

The first P-N junction element D1 and second P-N junction element D2 are configured with junction areas of relative size such that the second P-N junction element D2 has a junction area with a relative size of one, and the first P-N junction element D1 has a junction area that is N times the size of the second P-N junction element D2. As stated earlier, two diodes of different sizes, but with the same emitter current, will have different current densities and, as a result, slightly different voltage drops across the P-N junction. Similarly, because different current densities result in different voltage drops, the two diodes may also be selected to have the same size (i.e., N=1) and the circuit designed to provide different currents through the two diodes.

Furthermore, P-N junctions have a negative temperature coefficient wherein changes in the voltage drop across the P-N junction are inversely related to changes in temperature. In other words, as temperature rises, the voltage drop across a P-N junction falls. For example, for silicon, V_{be} is inversely related to temperature changes at about −2.2 mV/° C. Thus, the difference in current density creates a slightly different voltage drop across the first P-N junction element D1 relative to the second P-N junction element D2.

In analyzing the circuit of FIG. 5A, it can be shown, and those of ordinary skill in the art will recognize, that the voltage across a diode may be expressed as approximately,

$$VD = ( \frac{kT}{q} ) ln ( \frac{I}{Is * A} ) \qquad ( 1 )$$

where k is Boltzmann's constant, which equals about 1.3806×10−23 Joules/° K, q is electron charge, which equals about 1.602×10−19 Coulombs, T is absolute temperature in ° Kelvin, I is the forward current through the diode, I is represents a reverse saturation current of the diode, and A is the area of the P-N junction. The term kT/q is often referred to as the thermal voltage (VT). Thus, at room temperature of 300 ° K, VT equals about 26 millivolts.

Parameters for obtaining substantial temperature independence may be defined by envisioning the circuit as a feedback circuit wherein the reset signal 130 is fed back as a current source for the first resistance element R1 and the second resistance element R2, rather than VCC. In the feedback model, the comparator 140 operates to move the voltage of the first voltage signal 110 and the voltage of the second voltage signal 120 to substantially the same voltage. Thus,
V_{be2}=V_{R3}+V_{be1} (2)

VR3 may also be referred to as ΔV_{be} because it represents the difference in voltage drop between the second P-N junction element D2 and the first P-N junction element D1. Substituting in the diode equation, ΔV_{be} may be represented as,

$$\begin{matrix}Δ {V}_{be} = {V}_{be 2} - {V}_{be 1} \\ = ( \frac{kT}{q} ) ln ( \frac{I 2}{Is * A 2} ) - ( \frac{kT}{q} ) ln ( \frac{I 1}{Is * A 1} ) \\ = ( \frac{kT}{q} ) ln ( \frac{I 2 * A 1}{I 1 * A 2} )\end{matrix} \qquad ( 3 )$$

If resistance elements R1 and R2 are selected to have the same resistance, at a steady state the first voltage signal 110 is substantially equal to the voltage at the second voltage signal 120 and a first current I1 (also referred to as a reference current) will be substantially equal to a second current I2. Under these conditions, equation 2 may be written as,

$$Δ {V}_{be} = \frac{kT}{q} ln ( N ) = VT ln ( N ) \qquad ( 4 )$$

where N equals the ratio of P-N junction area between the first P-N junction element D1 and the second P-N junction element D2.

In the feedback model, the voltage on the reset signal 130 will be the sum of the voltage drops across the second resistance element R2 and the second P-N junction element D2, which may be written as,
Vout=V_{be2}+V_{R2} (5)

In addition, the first current I1 equals the sum of a sub-current I1a (also referred to as a first portion) and a sub-current I1b (also referred to as a second portion), as represented by the equation,

$$I 1 = I 1 a + I 1 b = \frac{Δ {V}_{be}}{R 3} + \frac{V 1}{R 4} \qquad ( 6 )$$

where V1 indicates the voltage at the first voltage signal 110. However, with feedback in a steady state, V1 equals V_{be2} so equation 6 may be written as,

$$I 1 = I 1 a + I 1 b = \frac{Δ {V}_{be}}{R 3} + \frac{{V}_{be 2}}{R 4} \qquad ( 7 )$$

Therefore, the voltage drop across the first resistance element R1 is,

$${V}_{R 1} = R 1 * I 1 = ( \frac{R 1}{R 3} ) Δ {V}_{be} + ( \frac{R 1}{R 4} ) {V}_{be 2} \qquad ( 8 )$$

In a steady state, V_{R2} equals V_{R1}. As a result, Vout from equation 5 may be written as,

$$Vout = {V}_{be 2} + ( \frac{R 1}{R 3} ) Δ {V}_{be} + ( \frac{R 1}{R 4} ) {V}_{be 2} \qquad ( 9 )$$

From this equation, parameter sets may be defined that meet a voltage on the reset signal 130 that is greater than the bandgap voltage of about 1.25 volts, while still maintaining substantial temperature independence wherein the change in voltage of the reset signal 130 relative to a change in temperature is substantially near zero. In other words,

$$\frac{ⅆ Vout}{ⅆ T} \approx 0$$

For example, in the case of R1=R2=240 Kohms, R3=15 Kohms, R4=400 Kohms, and N=8, a Vout of about 2.2V can be obtained.

In contrast, analyzing the prior art circuit of FIG. 1, yields an equation for the current 12, which may be represented as,

$$I 1 = \frac{Δ {V}_{be}}{{R}_{36}} \qquad ( 10 )$$

Therefore, the voltage drop across the resistance element 22 is,

$${V}_{32} = {R}_{32} * I 1 = ( \frac{{R}_{32}}{{R}_{36}} ) Δ {V}_{be} \qquad ( 11 )$$

Thus, in a steady state and with V₂₂ equal to V₃₂, the Vout of FIG. 1 may be written as,

$$Vout = {V}_{be 1} + ( \frac{{R}_{32}}{{R}_{36}} ) Δ {V}_{be} \qquad ( 12 )$$

In other words, Vout for the prior art circuit of FIG. 1 may be written as Vout=V_{be1}+A*V_{be}. Whereas, in embodiments of the present invention, Vout may be written as Vout=V_{be1}+B*ΔV_{be}+C*V_{be1}.

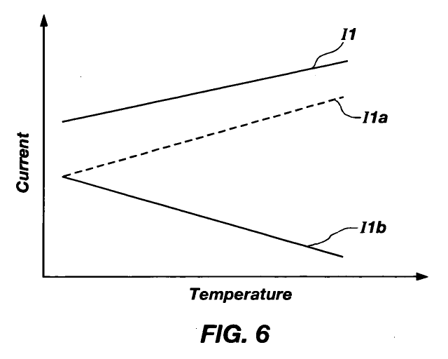

The current I1 may be represented graphically as in FIG. 6. Current I1 is illustrated as the sum of sub-current I1a and sub-current I1b. It can be seen that sub-current I1a is proportional to absolute temperature (i.e., PTAT) due to the ΔVbe term in equation 7. Similarly, sub-current I1b is inversely related to temperature change due to the Vbe2 term in equation 7. As a result, it can be seen how the current generator 160 (shown in FIGS. 3 and 4) can create the reference current I1 (i.e., Iptco) with a positive temperature coefficient from the Ia portion of reference current I1 and an additional offset current from the I1b portion of reference current I1.

The discussion above used feedback to define operational parameters that may be selected such that the reset circuit 100 generates a reset signal 130 that is substantially temperature independent. However, in the actual embodiments illustrated in FIGS. 3 and 4, the feedback is not used. The parameters in the non-feedback case will define the supply voltage 105, at which a transition will occur on the reset signal 130.

FIG. 5B is a circuit diagram of another embodiment of the present invention for generating a reset signal at a supply voltage above the bandgap voltage. This embodiment is similar to the embodiment of FIG. 5A except that rather than coupling directly to supply voltage 105, Resistors R1 and R2 are coupled to resistor R5, which is coupled to supply voltage 105. This configuration creates a voltage divider between the supply voltage 105 and the inputs of the comparator 140. Thus, the overall supply voltage 105 at which the power-on-reset signal is asserted may be raised while still maintaining substantial temperature independence.

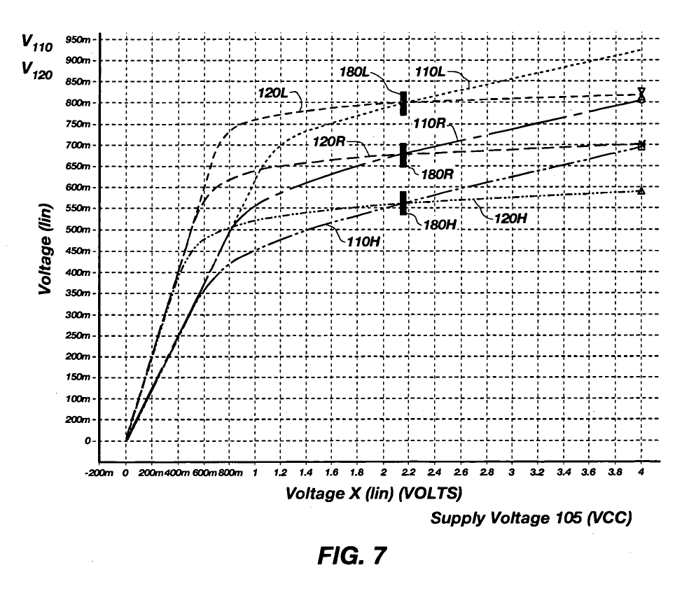

Without the feedback, operation of the reset circuit 100 may be examined, at various temperatures, as the power-on-reset voltage relative to supply voltage 105. FIG. 7 illustrates simulations of the first voltage signal 110 and the second voltage signal 120 along the y-axis relative to the supply voltage 105 along the x-axis. Lines 110L, 110R, and 110H illustrate voltages on the first voltage signal 110 at low temperature, room temperature, and high temperature, respectively. Similarly, lines 120L, 120R, and 120H illustrate voltages on the second voltage signal 120 at low temperature, room temperature, and high temperature, respectively.

In operation, the supply voltage 105 is applied and ramps up from zero to an intended VCC level. As the supply voltage 105 rises, the voltage levels on the first voltage signal 110 and the second voltage signal 120 also rise. However, they rise at different rates from each other. The second voltage signal 120 rises with a classical diode curve with a sharp rise in voltage relative to the rise of the supply voltage 105, then substantially flattens out after the supply voltage 105 exceeds the voltage drop across the second P-N junction element D2. The first voltage signal 110, on the other hand, includes the current generator 160 with a positive temperature coefficient and offset current. As a result, the first voltage signal 110 initially rises at a slower rate as the supply voltage 105 rises, but does not flatten out as significantly. This difference in voltage change results in the comparator 140 generating a low voltage as the supply voltage 105 rises until a transition point, where the first voltage signal 110 surpasses the second voltage signal 120 and the reset signal 130 is asserted.

Referring to the high temperature signals it can be seen that at low supply voltage 105 the first voltage signal 110H starts out at a lower voltage than the second voltage signal 120H. At a supply voltage 105 of about 2.2 volts, the first voltage signal 110H crosses over the second voltage signal 120H to be higher than the first voltage signal 110H. At this transition point 180H, the reset signal 130 will switch from a negated state to an asserted state, indicating that valid and substantially stable supply voltage 105 is present.

Referring to the room temperature signals, it can be seen that at low supply voltage 105 the first voltage signal 110R starts out at a lower voltage than the second voltage signal 120R. At a supply voltage 105 of about 2.2 volts, the first voltage signal 110R crosses over the second voltage signal 120R to be higher than the first voltage signal 110R. At this transition point 180R, the reset signal 130 will switch from a negated state to an asserted state, indicating that valid and substantially stable supply voltage 105 is present.

Referring to the low temperature signals, it can be seen that at low supply voltage 105 the first voltage signal 110L starts out at a lower voltage than the second voltage signal 120L. At a supply voltage 105 of about 2.2 volts, the first voltage signal 110L crosses over the second voltage signal 120L to be higher than the first voltage signal 110. At this transition point 180L, the reset signal 130 will switch from a negated state to an asserted state, indicating that valid and substantially stable supply voltage 105 is present.

Although the transition points (180L, 180R, and 180H) occur at different voltages (for first voltage signal 110 and second voltage signal 120) for different temperatures, it can be seen that the transition points (180L, 180R, and 180H) all occur at about the same supply voltage 105. Thus, the point at which the reset signal 130 is asserted is substantially temperature independent and may be set at a desired voltage above the bandgap voltage by proper selection of the parameter sets for the ratio of p-n junction element areas and resistance values for the resistance elements.

Embodiments of the present invention, while primarily described in relation to semiconductor memories, are applicable to many semiconductor devices. By way of example, any semiconductor device requiring a power-on-reset signal to occur at a supply voltage above the bandgap voltage may use the present invention.

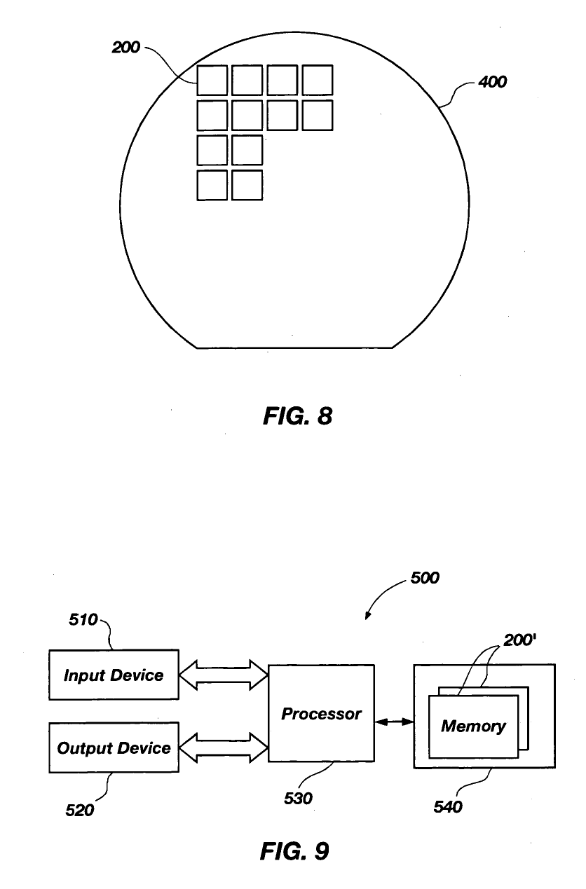

As shown in FIG. 8, a semiconductor wafer 400, in accordance with the present invention, includes a plurality of semiconductor devices 200, each semiconductor device 200 incorporating at least one embodiment of the reset circuits or methods described herein. Of course, it should be understood that the semiconductor devices 200 may be fabricated on substrates other than a silicon wafer, such as, for example, a Silicon On Insulator (SOI) substrate, a Silicon On Glass (SOG) substrate, and a Silicon On Sapphire (SOS) substrate.

As shown in FIG. 9, an electronic system 500, in accordance with the present invention, comprises an input device 510, an output device 520, a processor 530, and a memory device 540. The memory device 540 comprises at least one semiconductor memory 200′ incorporating at least one embodiment of the reset circuits or methods described herein in a DRAM device. It should be understood that the semiconductor memory 200′ might comprise a wide variety of devices other than a DRAM, including, for example, Static RAM (SRAM) devices, and Flash memory devices.

While the present invention has been described herein with respect to certain preferred embodiments, those of ordinary skill in the art will recognize and appreciate that it is not so limited. Rather, many additions, deletions, and modifications to the preferred embodiments may be made without departing from the scope of the invention as hereinafter claimed. In addition, features from one embodiment may be combined with features of another embodiment while still being encompassed within the scope of the invention as contemplated by the inventors.

1. A reset circuit, comprising:
a first resistance element operably coupled between a supply voltage and a first voltage signal;
a current generator operably coupled to the first voltage signal and configured for sinking a reference current having a positive temperature coefficient and an offset current;
a voltage generator configured for generating a second voltage signal having a negative temperature coefficient; and
a comparator configured for comparing the first voltage signal to the second voltage signal to generate a reset signal.

2. The reset circuit of claim 1, wherein the voltage generator comprises:
a second resistance element operably coupled between the supply voltage and the second voltage signal; and
a second P-N junction element operably coupled in a forward bias direction between the second voltage signal and a ground.

3. The reset circuit of claim 2, wherein the second P-N junction element comprises a device selected from the group consisting of a diode, a diode connected bipolar transistor, and a diode connected CMOS transistor.

4. The reset circuit of claim 1, wherein the current generator comprises:
a third resistance element operably coupled to the first voltage signal;
a fourth resistance element operably coupled between the first voltage signal and a ground; and
a first P-N junction element operably coupled in series with the third resistance element in a forward bias direction between the third resistance element and the ground.

5. The reset circuit of claim 4, wherein the first P-N junction element comprises a device selected from the group consisting of a diode, a diode connected bipolar transistor, and a diode connected CMOS transistor.

6. The reset circuit of claim 1, wherein the comparator comprises a differential amplifier.

7. A reset circuit, comprising:
a comparator having a first input, a second input, and a comparison result configured as a reset signal;
a first resistance element operably coupled between a supply voltage and the first input;
a third resistance element operably coupled to the first input;
a first P-N junction element operably coupled in series with the third resistance element in a forward bias direction between the third resistance element and a ground;
a fourth resistance element operably coupled between the first input and the ground;
a second resistance element operably coupled between the supply voltage and the second input; and
a second P-N junction element operably coupled in a forward bias direction between the second input and the ground.

8. The reset circuit of claim 7, wherein the first P-N junction element comprises a device selected from the group consisting of a diode, a diode connected bipolar transistor, and a diode connected CMOS transistor.

9. The reset circuit of claim 7, wherein the second P-N junction element comprises a device selected from the group consisting of a diode, a diode connected bipolar transistor, and a diode connected CMOS transistor.

10. The reset circuit of claim 7, wherein the comparator comprises a differential amplifier.

11. A reset circuit, comprising:
a comparator having a first input, a second input, and a comparison result configured as a reset signal;
a first resistance element operably coupled between an intermediate node and the first input;
a second resistance element operably coupled between the intermediate node and the second input;
a third resistance element operably coupled to the first input;
a first P-N junction element operably coupled in series with the third resistance element in a forward bias direction between the third resistance element and a ground;
a fourth resistance element operably coupled between the first input and the ground;
a fifth resistance element operably coupled between the intermediate node and a supply voltage; and
a second P-N junction element operably coupled in a forward bias direction between the second input and the ground.

12. The reset circuit of claim 11, wherein the first P-N junction element comprises a device selected from the group consisting of a diode, a diode connected bipolar transistor, and a diode connected CMOS transistor.

13. The reset circuit of claim 11, wherein the second P-N junction element comprises a device selected from the group consisting of a diode, a diode connected bipolar transistor, and a diode connected CMOS transistor.

14. The reset circuit of claim 11, wherein the comparator comprises a differential amplifier.

15. A semiconductor device including at least one reset circuit, comprising:
a first resistance element operably coupled between a supply voltage and a first voltage signal;
a current generator operably coupled to the first voltage signal and configured for sinking a reference current having a positive temperature coefficient and an offset current;
a voltage generator configured for generating a second voltage signal having a negative temperature coefficient; and
a comparator configured for comparing the first voltage signal to the second voltage signal to generate a reset signal.

16. The semiconductor device of claim 15, wherein the current generator comprises:
a third resistance element operably coupled to the first voltage signal;
a fourth resistance element operably coupled between the first voltage signal and a ground; and
a first P-N junction element operably coupled in series with the third resistance element in a forward bias direction between the third resistance element and the ground.

17. The semiconductor device of claim 16, wherein the first P-N junction element comprises a device selected from the group consisting of a diode, a diode connected bipolar transistor, and a diode connected CMOS transistor.

18. The semiconductor device of claim 15, wherein the voltage generator comprises:
a second resistance element operably coupled between the supply voltage and the second voltage signal; and
a second P-N junction element operably coupled in a forward bias direction between the second voltage signal and a ground.

19. The semiconductor device of claim 18, wherein the second P-N junction element comprises a device selected from the group consisting of a diode, a diode connected bipolar transistor, and a diode connected CMOS transistor.

20. The semiconductor device of claim 15, wherein the comparator comprises a differential amplifier.

21. A semiconductor wafer, comprising:
at least one semiconductor device including at least one reset circuit, comprising:
a first resistance element operably coupled between a supply voltage and a first voltage signal;
a current generator operably coupled to the first voltage signal and configured for sinking a reference current having a positive temperature coefficient and an offset current;
a voltage generator configured for generating a second voltage signal having a negative temperature coefficient; and
a comparator configured for comparing the first voltage signal to the second voltage signal to generate a reset signal.

22. The semiconductor wafer of claim 21, wherein the voltage generator comprises:
a second resistance element operably coupled between the supply voltage and the second voltage signal; and
a second P-N junction element operably coupled in a forward bias direction between the second voltage signal and a ground.

23. The semiconductor wafer of claim 22, wherein the second P-N junction element comprises a device selected from the group consisting of a diode, a diode connected bipolar transistor, and a diode connected CMOS transistor.

24. The semiconductor wafer of claim 21, wherein the current generator comprises:
a third resistance element operably coupled to the first voltage signal;
a fourth resistance element operably coupled between the first voltage signal and a ground; and
a first P-N junction element operably coupled in series with the third resistance element in a forward bias direction between the third resistance element and the ground.

25. The semiconductor wafer of claim 24, wherein the first P-N junction element comprises a device selected from the group consisting of a diode, a diode connected bipolar transistor, and a diode connected CMOS transistor.

26. The semiconductor wafer of claim 21, wherein the comparator comprises a differential amplifier.

27. An electronic system, comprising:
at least one input device;
at least one output device;
a processor; and
a memory device comprising, at least one semiconductor memory including at least one reset circuit, comprising:
a first resistance element operably coupled between a supply voltage and a first voltage signal;
a current generator operably coupled to the first voltage signal and configured for sinking a reference current having a positive temperature coefficient and an offset current;
a voltage generator configured for generating a second voltage signal having a negative temperature coefficient; and
a comparator configured for comparing the first voltage signal to the second voltage signal to generate a reset signal.

28. The electronic system of claim 27, wherein the voltage generator comprises:
a second resistance element operably coupled between the supply voltage and the second voltage signal; and
a second P-N junction element operably coupled in a forward bias direction between the second voltage signal and a ground.

29. The electronic system of claim 28, wherein the second P-N junction element comprises a device selected from the group consisting of a diode, a diode connected bipolar transistor, and a diode connected CMOS transistor.

30. The electronic system of claim 27, wherein the current generator comprises:
a third resistance element operably coupled to the first voltage signal;
a fourth resistance element operably coupled between the first voltage signal and a ground; and
a first P-N junction element operably coupled in series with the third resistance element in a forward bias direction between the third resistance element and the ground.

31. The electronic system of claim 30, wherein the first P-N junction element comprises a device selected from the group consisting of a diode, a diode connected bipolar transistor, and a diode connected CMOS transistor.

32. The electronic system of claim 27, wherein the comparator comprises a differential amplifier.

33. A method, comprising:
generating a reference current having a positive temperature coefficient and an offset current;
generating a first voltage signal as a voltage drop from a supply voltage, by guiding the reference current through a first resistance element operably coupled between the supply voltage and the reference current;
generating a second voltage signal having a negative temperature coefficient; and
comparing the first voltage signal to the second voltage signal to generate a reset signal.

34. The method of claim 33, wherein generating the reference current comprises:
directing the first voltage signal through a third resistance element; and
directing the first voltage signal through a series combination of a fourth resistance element and a forward biased first P-N junction element.

35. The method of claim 33, wherein generating the second voltage signal comprises creating a voltage drop across a second P-N junction element.

36. The method of claim 33, wherein comparing further comprises:
applying the first voltage signal to a first input of a differential amplifier;
applying the second voltage signal to a second input of the differential amplifier; and
generating the reset signal for an output of the differential amplifier.
